(19) United States
(12) Patent Application Publication
(10) Pub. No.: US 2013/0248352 A1
(43) Pub. Date: Sep. 26, 2013

(54) Multiple Frequency Sputtering for Enhancement in Deposition Rate and Growth Kinetics of Dielectric Materials

(71) Applicants: Chong Jiang, Cupertino, CA (US); Byung-Sung Leo Kwak, Portland, OR (US); Michael Stowell, Loveland, CO (US); Karl Armstrong, San Jose, CA (US)

(72) Inventors: Chong Jiang, Cupertino, CA (US); Byung-Sung Leo Kwak, Portland, OR (US); Michael Stowell, Loveland, CO (US); Karl Armstrong, San Jose, CA (US)

(73) Assignee: Applied Materials, Inc., Santa Clara, CA (US)

(21) Appl. No.: 13/609,178

(22) Filed: Sep. 10, 2012

Related U.S. Application Data
(60) Provisional application No. 61/533,074, filed on Sep. 9, 2011.

(51) Int. Cl. C23C 14/34

(52) U.S. Cl. CPC C23C 14/345
USPC 204/192.22; 204/298.08; 204/298.06

(57) ABSTRACT

A method of sputter depositing dielectric thin films may comprise: providing a substrate on a substrate pedestal in a process chamber, the substrate being positioned facing a sputter target; simultaneously applying a first RF frequency from a first power supply and a second RF frequency from a second power supply to the sputter target; and forming a plasma in the process chamber between the substrate and the sputter target, for sputtering the target; wherein the first RF frequency is less than the second RF frequency, the first RF frequency is chosen to control the ion energy of the plasma and the second RF frequency is chosen to control the ion density of the plasma. The self-bias of surfaces within said process chamber may be selected; this is enabled by connecting a blocking capacitor between the substrate pedestal and ground.

### CROSS-REFERENCE TO RELATED APPLICATIONS

This application claims the benefit of U.S. Provisional Application No. 61/533,074 filed Sep. 9, 2011, incorporated herein by reference in its entirety.

### FIELD OF THE INVENTION

Embodiments of the present invention relate generally to equipment for dielectric thin film deposition and more specifically to sputtering equipment for dielectric thin films including multiple frequency power sources for the sputter target.

### BACKGROUND OF THE INVENTION

Typically dielectric materials, such as Li₃PO₄ to form LiPON (lithium phosphorus oxynitride), primarily because of their very low electrical conductivity, require high frequency power supplies (RF) to enable (PVD) sputtering of dielectric targets for thin film deposition. In addition, these dielectric materials typically have low thermal conductivity which limits the sputtering process at high frequency to lower power density regimes, in order to avoid problems such as thermal gradient induced stresses in the sputtering target that may lead to cracking and particle generation. The limitation to low power density regimes results in relatively low deposition rates, which in turn leads to high capital expenditure requirements for manufacturing systems with higher throughput capacity. Despite these limitations, and for wont of a better solution, conventional RF PVD techniques are being used to deposit dielectric materials in high volume manufacturing processes for electrochemical devices such as thin film batteries (TFBs) and electrochromic (EC) devices.

Clearly, there is a need for improved equipment and methods for reducing the cost of dielectric deposition in high throughput electrochemical device manufacturing. Furthermore, there is a need for improved deposition methods for dielectric thin films in general, including thin films of oxides, nitrides, oxynitrides, phosphates, sulfides, selenides, etc. Yet furthermore, there is a need for improved control of crystallinity, morphology, grain structure etc. for dielectric films.

### SUMMARY OF THE INVENTION

The present invention relates, in general, to systems and methods for improving deposition of dielectric thin films which include the use of dual frequency target power sources for improved sputtering rates, improved thin film quality and reduced thermal stress in the target. The dual RF frequencies provide independent control of plasma ion density and ion energies, by using, respectively, higher frequency and lower frequency RF target power sources. The present invention is generally applicable to PVD sputter deposition tools for dielectric materials. Specific examples are lithium containing electrolyte materials, e.g., lithium phosphorus oxynitride (LiPON) formed by sputtering lithium orthophosphate (and some variations thereof), typically in a nitrogen gas ambient. Such materials are used in electrochemical devices, such as TFBs (thin film batteries) and EC devices (electrochromic devices). Examples of other dielectric thin films to which the present invention is applicable include thin films of oxides, nitrides, oxynitrides, phosphates, sulfides and selenides. The present invention may provide improved control of crystallinity, morphology, grain structure etc. of the deposited dielectric thin films.

According to some embodiments of the present invention, a method of sputter depositing dielectric thin films may comprise: providing a substrate on a substrate pedestal in a process chamber, the substrate being positioned facing a sputter target; simultaneously applying a first RF frequency from a first power supply and a second RF frequency from a second power supply to the sputter target; and forming a plasma in the process chamber between the substrate and the sputter target, for sputtering the target; wherein the first RF frequency is less than the second RF frequency, the first RF frequency is chosen to control the ion energy of the plasma and the second RF frequency is chosen to control the ion density of the plasma. The self-bias of surfaces within said process chamber may be selected; this is enabled by connecting a blocking capacitor between the substrate pedestal and ground. Furthermore, other power sources, including DC sources, pulsed DC sources, AC sources, and/or RF sources, may be applied in combination with, or replacing one of, the dual RF power sources, to the target, plasma, and/or substrate.

Some embodiments of deposition equipment for dual RF dielectric thin film sputter deposition are described herein.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a schematic representation of a process chamber with a dual frequency sputter target power supply, according to some embodiments of the present invention;

FIG. 2 is a schematic representation of a process chamber with multiple power sources, according to some embodiments of the present invention;

FIG. 3 is a representation of a process chamber with multiple power sources and a rotating cylindrical target, according to some embodiments of the present invention;

FIG. 4 is a cut-away representation of part of a dual frequency sputter target power source, according to some embodiments of the present invention;

FIG. 5 is a cut-away representation of part of a prior art sputter target power source;

FIG. 6 is a graph of ion energy and ion density against sputter target power source frequency, due to Werbaneth et al.;

FIG. 7 is a graph of sputter yield against ion energy for a sputter deposition system according to some embodiments of the present invention;

FIG. 8 is a graph of sputter yield against ion angle of incidence for a sputter deposition system according to some embodiments of the present invention;

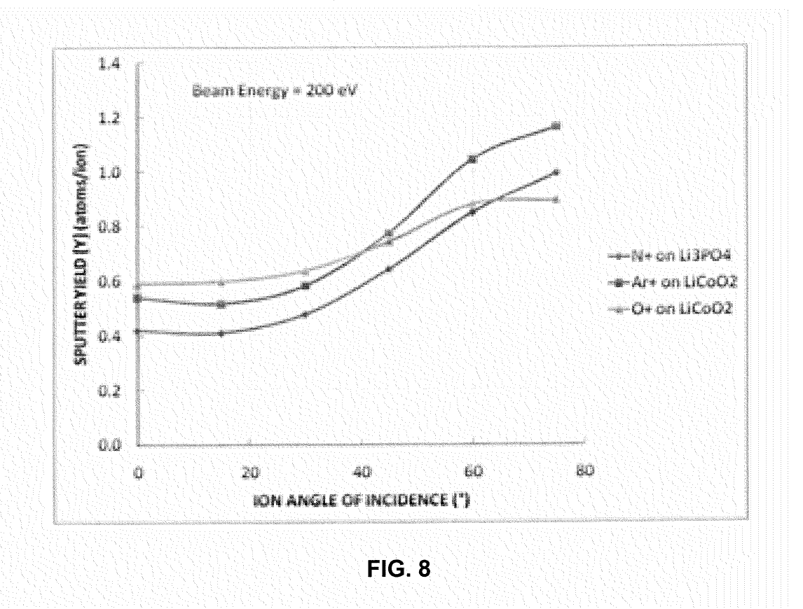

FIG. 9 is a cartoon illustrating various possibilities for adatom placement;

FIG. 10 is a schematic illustration of a thin film deposition cluster tool, according to some embodiments of the present invention;

FIG. 11 is a representation of a thin film deposition system with multiple in-line tools, according to some embodiments of the present invention; and

FIG. 12 is a representation of an in-line sputter deposition tool, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

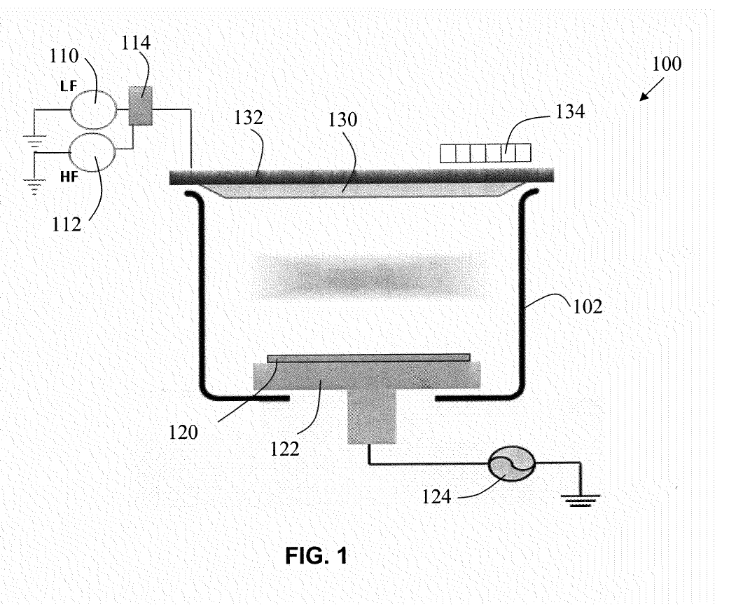

FIG. 1 schematically depicts a sputter deposition tool 100 with a vacuum chamber 102 and with dual frequency RF target power sources—one source 110 at a lower RF frequency and the other source 112 at a higher RF frequency. The RF sources are electrically connected to a target back plate 132 through a matching network 114. The substrate 120 sits on a pedestal 122 that is capable of modulating the substrate temperature and of applying bias power from a power supply 124 to the substrate. The target 130 is attached to the back plate 132 and is shown as a magnetron sputter target with a moving magnet 134; however, the approach of the present invention is agnostic to the specific configuration of the sputter target. FIG. 1 illustrates a target source configuration that can be used to provide better control of the plasma properties, allowing higher throughput for dielectric targets with poor electrical conductivity and higher quality deposited thin films, as described in more detail below. Furthermore, power supply 124 may be replaced by a blocking capacitor—the blocking capacitor is connected between the substrate pedestal and ground.

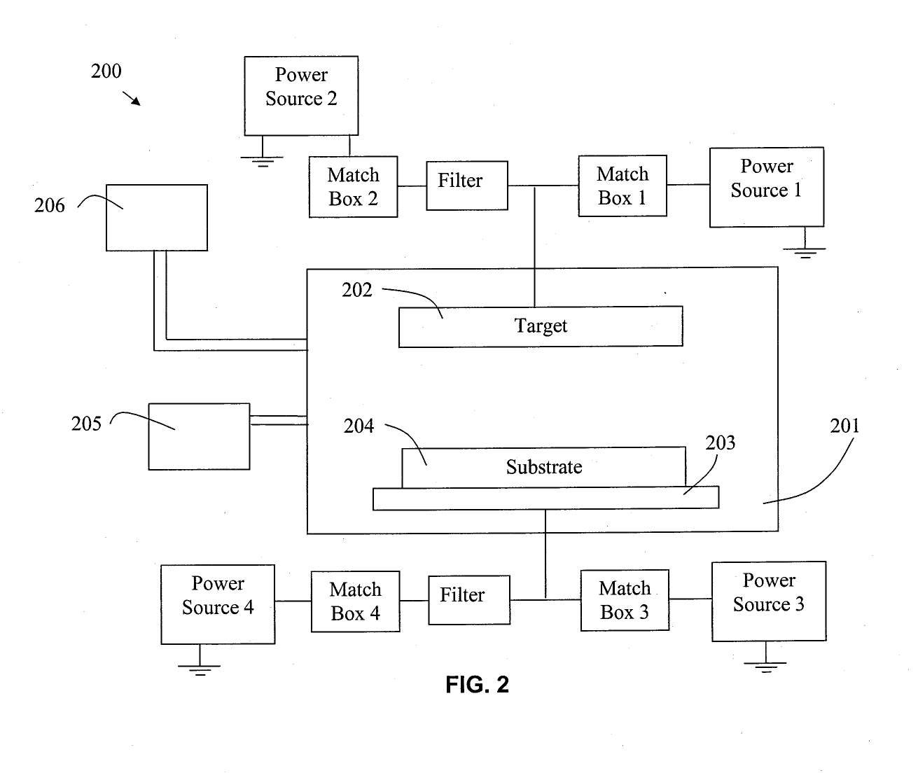

More detailed examples of sputter deposition systems according to the present invention are shown in FIGS. 2 & 3—these systems are plasma systems for which combinations of a variety of different power sources may be employed, such as the combination of low and high frequency RF sources described above with reference to FIG. 1. FIG. 2 shows a schematic representation of an example of a deposition tool 200 configured for deposition methods according to the present invention. The deposition tool 200 includes a vacuum chamber 201, a sputter target 202 and a substrate pedestal 203 for holding a substrate 204. (For LiPON deposition the target 202 may be Li₃PO₄ and a suitable substrate 204 may be silicon, silicon nitride on Si, glass, PET (polyethylene terephthalate), mica, metal foils, etc., with current collector and cathode layers already deposited and patterned.) The chamber 201 has a vacuum pump system 205 for controlling the pressure in the chamber and a process gas delivery system 206. Multiple power sources may be connected to the target. Each target power source has a matching network for handling radio frequency (RF) power supplies. A filter is used to enable use of two power sources connected to the same target/substrate to operate at different frequencies, where the filter acts to protect the target/substrate power supply operating at the lower frequency from damage due to the higher frequency power. Similarly, multiple power sources may be connected to the substrate. Each power source connected to the substrate has a matching network for handling radio frequency (RF) power supplies. Furthermore, as described above with reference to FIG. 1, a blocking capacitor may be connected to the substrate pedestal 203 in order to induce a different pedestal/chamber impedance to modulate the self-bias of surfaces within the process chamber, including the target and substrate, and thereby induce different: (1) sputtering yields on the target and (2) kinetic energy of adatoms, for modulation of growth kinetics. The capacitance of the blocking capacitor may be adjusted in order to change the self-bias at the different surfaces within the process chamber, importantly the substrate surface and the target surface.

Although FIG. 2 shows a chamber configuration with horizontal planar target and substrate, the target and substrate may be held in vertical planes—this configuration can assist in mitigating particle problems if the target itself generates particles. Furthermore, the position of the target and substrate may be switched, so that the substrate is held above the target. Yet furthermore, the substrate may be flexible and moved in front of the target by a reel to reel system, the target may be a rotating or oscillating cylindrical target, the target may be non-planar, and/or the substrate may be non-planar. Here the term oscillating is used to refer to limited rotational motion in any one direction such that a solid electrical connection to the target suitable for transmitting RF power can be accommodated. Furthermore, the match boxes and filters may be combined into a single unit for each power source. One or more of these variations may be utilized in deposition tools according to some embodiments of the present invention.

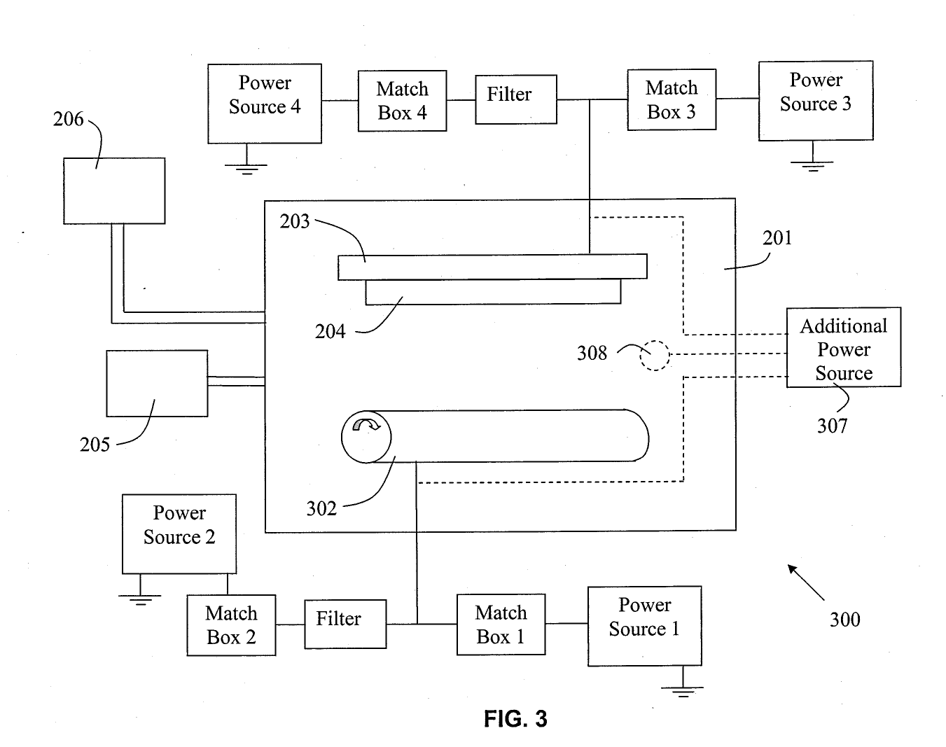

FIG. 3 shows an example of a deposition tool 300 with a single rotatable or oscillating cylindrical target 302. Dual rotatable cylindrical targets may also be used. Further, FIG. 3 shows the substrate held above the target. Furthermore, FIG. 3 shows an additional power source 307, which may be connected to either substrate or target, connected between target and substrate, or coupled directly to the plasma in the chamber using an electrode 308. An example of the latter is the power source 307 being a microwave power source coupled directly to the plasma using an antennae (electrode 308); although, microwave energy may be provided to the plasma in many other ways, such as at a remote plasma source. A microwave source for coupling directly with the plasma may include an electron cyclotron resonance (ECR) source.

According to aspects of the invention, different combinations of power sources may be used by coupling appropriate power sources to the substrate, target and/or plasma. Depending on the type of plasma deposition technique used, the substrate and target power sources may be chosen from DC sources, pulsed DC (pDC) sources, AC sources (with frequencies below RF, typically below 1 MHz), RF sources, etc, in any combinations thereof. The additional power source may be chosen from pDC, AC, RF, microwave, a remote plasma source, etc. RF power may be supplied in continuous wave (CW) or burst mode. Furthermore, the target may be configured as an HPPM (high-power pulsed magnetron). For example, combinations may include dual RF sources at the target, pDC and RF at the target, etc. (Dual RF at the target may be well suited for insulating dielectric target materials, whereas pDC and RF or DC and RF at the target may be used for conductive target materials. Furthermore, the substrate bias power source type may be chosen based on what the substrate pedestal can tolerate as well as the desired effect.)

Some examples of combinations of power sources are provided for deposition of a LiPON electrolyte layer of TFB using a Li₃PO₄ target (an insulating target material) in a nitrogen or argon ambient (the latter requiring a subsequent nitrogen plasma treatment, to provide the necessary nitrogen). (1) Dual RF sources (different frequencies) at the target and an RF bias at the substrate, where the frequency of the RF bias is different to the frequencies used at the target. (2) Dual RF at the target plus microwave plasma enhancement. (3) Dual RF at the target plus microwave plasma plus RF substrate bias, where the frequency of the RF bias can be different to the frequencies used at the target. Furthermore, a DC bias or a pDC bias is an option for the substrate.

For tungsten oxide cathode layer deposition of an EC device, ordinarily pDC sputtering of tungsten (a conductive target material) can be used; however, the deposition process may be enhanced by using pDC and RF at the target.

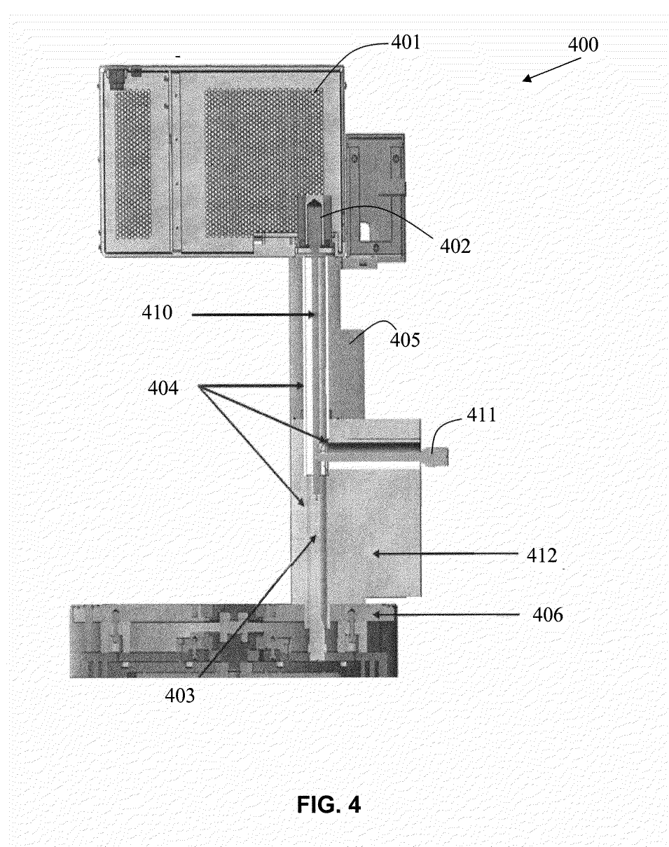

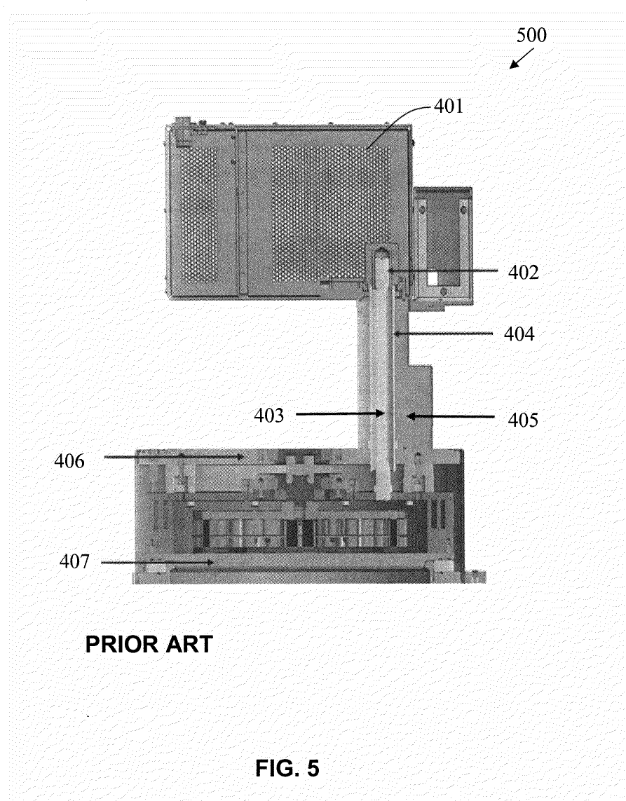

FIG. 4 shows a cut-away view of hardware configuration 400 for some embodiments of the dual frequency RF sputter target power sources of the present invention. (For comparison FIG. 5 shows a cut-away view of a conventional RF sputter chamber power source hardware configuration 500.) In FIG. 4, the power source is connected through the deposition chamber lid 406, which also supports the sputter target 407 (see FIG. 5). A conventional RF power feed 403 is used, along with RF feed extension rods 410 and 411. A dual frequency match box 401 is attached to the end of the vertical extension rod 410 by a match box connector 402. Structural support is provided by adapter 412 and mounting bracket 405 A low-pass filter is provided on the low frequency RF power supply side (along the horizontal extension bar 411, for example), which is necessary to block power from the high frequency RF source from being transmitted along the waveguide and damaging the low frequency RF power supply. The low frequency RF power supply will also have a match box; although the function of match box and filter may be combined in a single unit. The rods 403, 410 and 411 may be silver-plated copper RF rods and are insulated from the housing using Teflon insulators 404, for example. Some examples of operating frequencies are provided: (1) the lower frequency RF source may operate at 500 KHz to 2 MHz, while the higher frequency RF source may operate at 13.56 MHz and up; or (2) the lower frequency may operate at more than 2 MHz, perhaps 13.65 MHz, while the higher frequency may operate at 60 MHz, or higher. There is a minimum low frequency that is required for non-conducting targets in order to induce power transmission through the target for plasma formation—calculations suggest a minimum in the vicinity of 500 kHz to 1 MHz for typical dielectric sputter targets. The upper limit for the higher frequency may be limited by stray plasma generation, which occurs in corners and narrow gaps within the chamber at higher frequencies—the actual limit will depend on the chamber design.

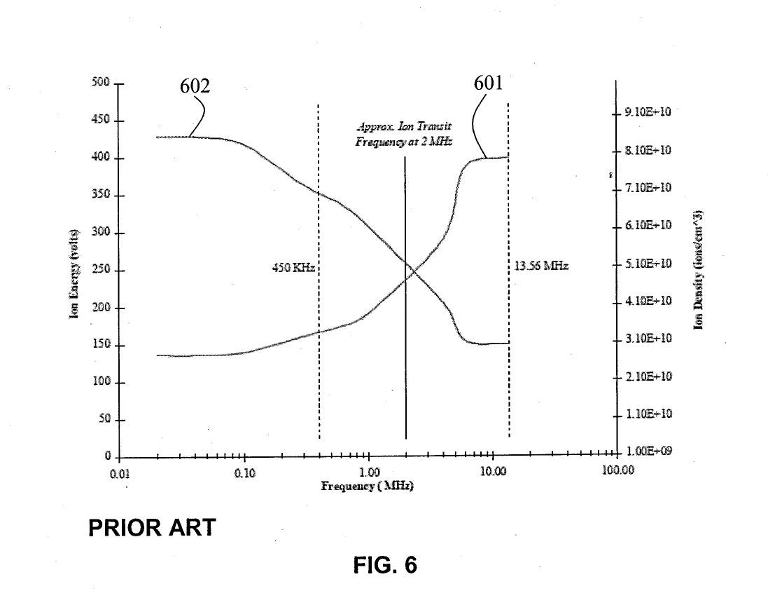

In order to enhance the sputter deposition rate for low electrical conductivity target materials some embodiments of the present invention use a source that can provide more independent control of the ion density and ion energy (self bias) of the plasma than can be achieved with a conventional single frequency RF power source. Both high ion density and high ion energy are desired for high deposition rates with reduced target heating, as explained below; however, as the RF frequency increases ion density increases and ion energy decreases. FIG. 6 shows the frequency dependence of ion density and ion energy (self bias) for an RF plasma due to a conventional single frequency RF power source—curves 601 and 602, respectively. (FIG. 2 from Werbaneth, P., Hasan, Z., Rajora, P., & Rousey-Seidel, M., The Reactive Ion Etching of Au on GaAs Substrates in a High Density Plasma Etch Reactor, The International Conference on Compound Semiconductor Manufacturing Technology, St Louis, 1999.) A solution provided by the present invention is to have dual frequency RF sources for the sputter target, where the lower frequency dominates the ion energy and the higher frequency is used to determine the ion density. The ratio of higher frequency to lower frequency in the dual RF sources is used to optimize the ion energy and plasma density to provide a sputter rate enhancement over that available with a single RF source.

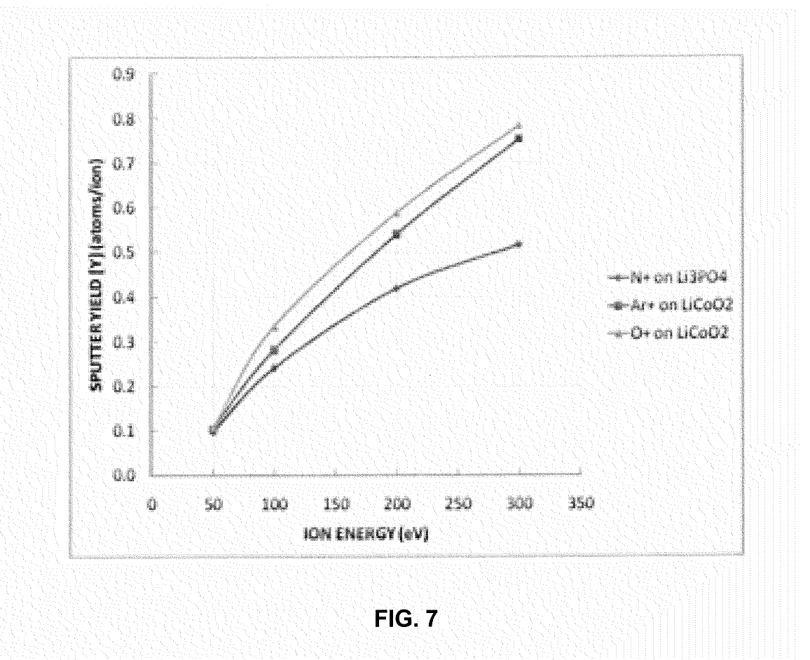

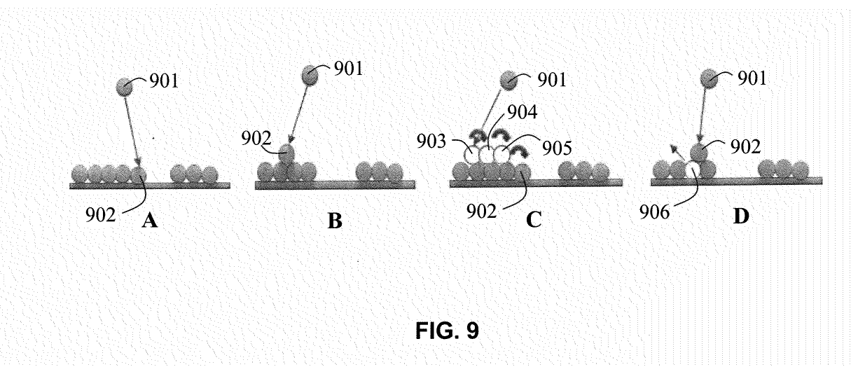

The fundamental and empirical limitations of RF sputtering of highly electrically resistive dielectric materials are considered in more detail, using TFB materials as an example. First, to deposit LiPON electrolyte from Li₃PO₄ targets, an RF sputtering PVD process is used since the material is highly resistive—approximately 2×10¹⁴ ohm-cm. This leads to sputtering species with relatively low ion energies (compared to sputtering at lower frequencies—see FIG. 6), leading to a low sputtering rate (see FIG. 7). The power can be increased to compensate for this limitation—increasing the source power will increase both the ion energy (or self-bias) and ion density. However, the typically low thermal conductivity of these dielectric materials can lead to high temperature gradients through the depth of the target from the sputtering surface, and thus to high thermal stresses in the target when operating at higher power. This situation results in an upper limit of power (normalized to the target area) that can be applied at a particular frequency, dictated by the strength of the target and thermal conductivity, above which the sputtering target will be unstable. If, in fact, the bias voltage or ion energy can be increased independent of such limitations (RF typically generates only 50 to 150 V of self bias at 13.56 MHz—see FIG. 6), then experiments show that the sputtering rate increases roughly linearly with the ion energy or the self bias. It is also found experimentally that the angle of incidence of these sputtering ions plays a role in determining the sputtering yield. These two observations are shown in FIGS. 7 & 8, where the sputtering yield is plotted with respect to the bias voltage (ion energy) of incoming species and the incident angle, respectively. FIGS. 7 & 8 include data for the following target materials and plasma species: Li₃PO₄ and N⁺, LiCoO₂ and Ar⁺, and LiCoO₂ and O₂⁺ systems. On the other hand, the higher ion density of higher frequency plasma may be beneficial from a broader perspective, particularly in enhancing the growth kinetics, as discussed in more detail below with reference to FIG. 9, if some of the high density ions and other energetic particles are allowed to impart energy to the growing film. The dual frequency source would independently modulate the ion energy and ion density by using, respectively, low frequency (LF) and high frequency (HF) RF power sources. In doing so, the dual frequency source, when compared with a single frequency RF source, is projected to achieve a higher sputter yield at a given total source power and to provide enhanced adatom surface mobility and improved growth kinetics.

Some embodiments of the present invention provide tools and methodologies that enhance the growth kinetics of dielectric thin film deposition so that the formation of a desired microstructure and phase (grain size, crystallinity, etc.) occurs more readily, especially at the higher deposition rates that are enabled by the sputter deposition sources with dual frequency RF target power supplies. Control of the growth kinetics may allow for control of a broad range of deposited thin film characteristics, including crystallinity, grain structure, etc. For example, control over growth kinetics may be used to reduce pinhole density in the deposited thin films.

Sputtered dielectric species typically have low surface mobility, leading to a high propensity for pinhole formation in thin films of these dielectrics. Pinholes in electrochemical devices may lead to device impairment or even failure. Such an enhancement in surface mobility will assist in the effort to achieve market-viable electrochemical devices and technologies, since achieving pinhole free, conformal electrolyte layers and doing so for thin films of lower thickness will lead to (1) higher yielding products, (2) higher throughput/capacity tools and (3) lower impedance and thus higher performing devices. The growth kinetics will now be considered in more detail.

In describing the deposition phenomena and pinhole formation in dielectric thin films, the surface mobility of the adatoms can be expressed in terms of the Ehrlich-Schwoebel barrier energy. Referring to situation C in FIG. 9, the Ehrlich-Schwoebel barrier is an activation energy necessary to induce the “arrowed” movement from a higher surface plane to a lower surface plane, as in shifting from situation B to C. The effect of such movement is planarization, reduced pin-hole density and better conformality. It is estimated that this barrier energy is in the range of 5 to 25 eV for a LiPON thin film. Again referring to the FIG. 9, where cartoons of possible scenarios for the final position 902 of an incoming adatom 901 are shown, various possible scenarios for an incoming adatom 901 include: (A) desired deposition, where the final position 902 of the adatom is filling a gap; (B) undesired deposition as pinholes can be created, since the final adatom position 902 is in a second layer before all the gaps in a first layer are filled; (C) desired deposition where the impinging adatom 901 has sufficient energy to overcome (or be induced to overcome) the Erlich-Schwoebel barrier, so that even though the adatom is first positioned in a second layer at position 903, there is sufficient energy for the adatom to move through positions 904 and 905, before coming to rest in final position 902 in a gap in the first layer; and (D) resputtering of adatoms caused by an incoming adatom 901 with high energy, sputtering away the atom in position 906. The goal is to add sufficient energy to the growing film so as not to affect the situation (A), which is the desired outcome, induce (C) for the situation (B), but not add too much energy to induce situation (D), which is the re-sputtering process. Whether additional energy needs to be added to the growing film to achieve the desired outcome will depend on the deposition rate and incoming adatom energy. Additional energy may be added by directly heating the substrate and/or creating a substrate plasma. Regarding the latter, the tertiary power source coupled to the substrate/pedestal may be used to achieve the following: (1) formation of a plasma which enhances the ion density effect of the dual sputtering source plasma on the substrate, and (2) formation of a self bias on the substrate to accelerate the incoming, charged adatoms/plasma species.

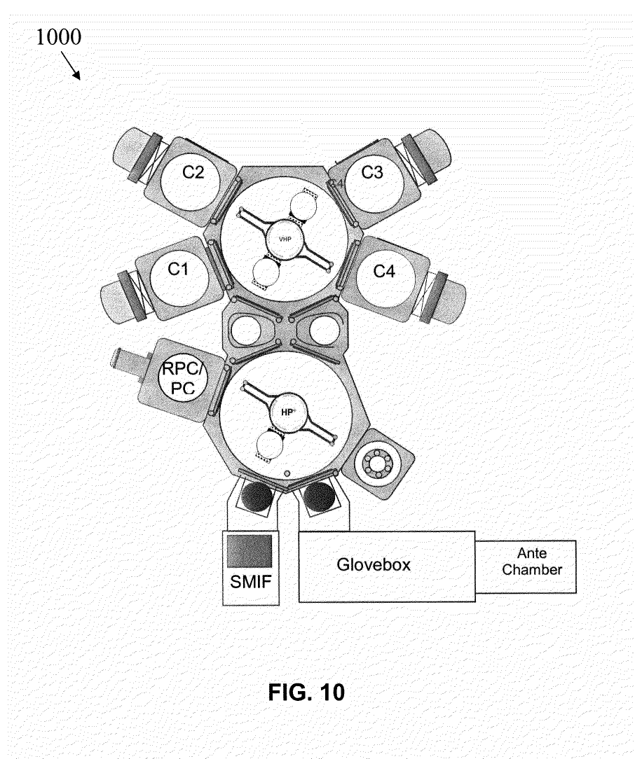

FIG. 10 is a schematic illustration of a processing system 600 for fabricating an electrochemical device such as a TFB or EC device, according to some embodiments of the present invention. The processing system 600 includes a standard mechanical interface (SMIF) to a cluster tool equipped with a reactive plasma clean (RPC) and/or sputter pre-clean (PC) chamber and process chambers C1-C4, which may include a dielectric thin film sputter deposition chamber as described above. A glovebox may also be attached to the cluster tool. The glovebox can store substrates in an inert environment (for example, under a noble gas such as He, Ne or Ar), which is useful after alkali metal/alkaline earth metal deposition. An ante chamber to the glovebox may also be used if needed—the ante chamber is a gas exchange chamber (inert gas to air and vice versa) which allows substrates to be transferred in and out of the glovebox without contaminating the inert environment in the glovebox. (Note that a glovebox can be replaced with a dry room ambient of sufficiently low dew point as such is used by lithium foil manufacturers.) The chambers C1-C4 can be configured for process steps for manufacturing thin film battery devices for example which may include: deposition of an electrolyte layer (e.g. LiPON by RF sputtering a Li₃PO₄ target in N₂) in a dual RF source deposition chamber, as described above. It is to be understood that while a cluster arrangement has been shown for the processing system 600, a linear system may be utilized in which the processing chambers are arranged in a line without a transfer chamber so that the substrate continuously moves from one chamber to the next chamber.

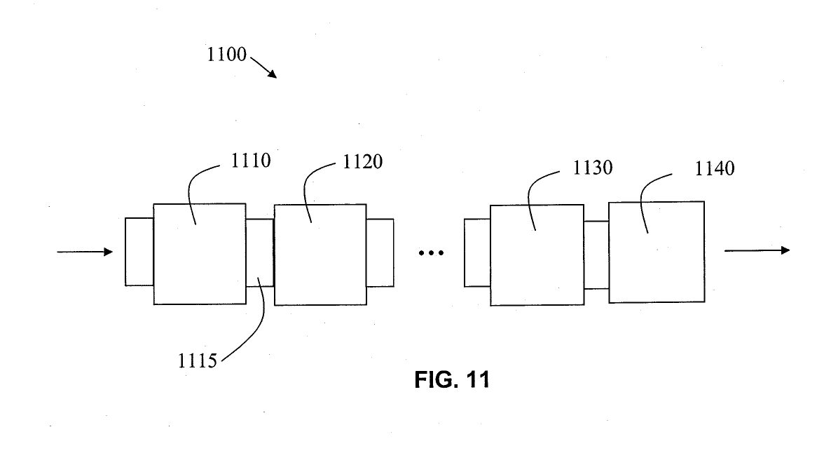

FIG. 11 shows a representation of an in-line fabrication system 1100 with multiple in-line tools 1110, 1120, 1130, 1140, etc., according to some embodiments of the present invention. In-line tools may include tools for depositing all the layers of an electrochemical device—including both TFBs and electrochromic devices. Furthermore, the in-line tools may include pre- and post-conditioning chambers. For example, tool 1110 may be a pump down chamber for establishing a vacuum prior to the substrate moving through a vacuum airlock 1115 into a deposition tool 1120. Some or all of the in-line tools may be vacuum tools separated by vacuum airlocks 1115. Note that the order of process tools and specific process tools in the process line will be determined by the particular electrochemical device fabrication method being used. For example, one or more of the in-line tools may be dedicated to sputter deposition of a thin film dielectric according to some embodiments of the present invention in which a dual RF frequency target source is used, as described above. Furthermore, substrates may be moved through the in-line fabrication system oriented either horizontally or vertically.

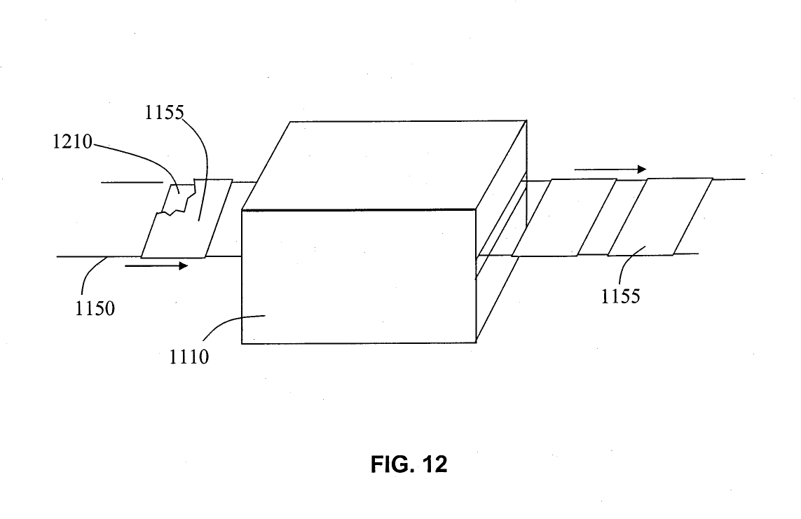

In order to illustrate the movement of a substrate through an in-line fabrication system such as shown in FIG. 11, in FIG. 12 a substrate conveyer 1150 is shown with only one in-line tool 1110 in place. A substrate holder 1155 containing a substrate 1210 (the substrate holder is shown partially cut-away so that the substrate can be seen) is mounted on the conveyer 1150, or equivalent device, for moving the holder and substrate through the in-line tool 1110, as indicated. A suitable in-line platform for processing tool 1110 with vertical substrate configuration is Applied Material's New Aristo™. A suitable in-line platform for processing tool 1110 with horizontal substrate configuration is Applied Material's Aton™.

The present invention is applicable generally to sputter deposition tools and methodologies for deposition of dielectric thin films. Although specific examples of processes are provided for PVD RF sputtering of a Li₃PO₄ target in a nitrogen ambient to form LiPON thin films, the processes of the present invention are applicable to the deposition of other dielectric thin films, such as thin films of SiO₂, Al₂O₃, ZrO₂, Si₃N₄, SiON, TiO₂, etc. and more generally to thin films of oxides, nitrides, oxynitrides, phosphates, sulfides, selenides, etc.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A method of sputter depositing dielectric thin films, comprising:
providing a substrate on a substrate pedestal in a process chamber, said substrate being positioned facing a sputter target;
simultaneously applying a first RF frequency from a first power supply and a second RF frequency from a second power supply to said sputter target; and
forming a plasma in said process chamber between said substrate and said sputter target, for sputtering said target;
wherein said first RF frequency is less than said second RF frequency, said first RF frequency is chosen to control the ion energy of said plasma and the second RF frequency is chosen to control the ion density of said plasma.

2. The method of claim 1, wherein said sputter target consists of an insulating material.

3. The method of claim 2, wherein said insulating material is lithium orthophosphate.

4. The method of claim 2, wherein said first RF frequency is greater than 500 kHz.

5. The method of claim 1, wherein said first RF frequency is in the range of 500 kHz to 2 MHz, and the second RF frequency is greater than or equal to 13.56 MHz.

6. The method of claim 1, wherein said first RF frequency is greater than 2 MHz, and said second RF frequency is greater than or equal to 60 MHz.

7. The method of claim 1, further comprising coupling an additional power source to said plasma.

8. The method of claim 7, wherein said additional power source is a microwave power source.

9. The method of claim 1, further comprising, during said sputter deposition, applying an RF bias to said substrate pedestal from a third power supply, the frequency of said RF bias being different to said first RF frequency and said second RF frequency.

10. The method of claim 1, further comprising, during said sputter deposition, applying a DC bias to said substrate pedestal.

11. The method of claim 1, further comprising, selecting the self-bias of surfaces within said process chamber.

12. The method as in claim 11, wherein the self-bias is selected by adjusting the capacitance of a blocking capacitor connected between said substrate pedestal and ground.

13. The method as in claim 11, wherein the self-bias of the surface of said substrate is selected.

14. A process system for sputter depositing dielectric thin films, comprising:
a process chamber;
a sputter target in said process chamber;
a substrate pedestal in said process chamber, said substrate pedestal being configured to hold a substrate facing said sputter target;
a first power supply for providing a first RF frequency and a second power supply for providing a second RF frequency to said sputter target, wherein said first RF frequency is less than said second RF frequency, said first RF frequency is chosen to control the ion energy of a plasma in said process chamber between said target and said substrate and the second RF frequency is chosen to control the ion density of said plasma; and
a filter connected between said first power supply and said second power supply and between one of said first power supply and said second power supply and said target, said filter being configured to enable said first RF frequency and said second RF frequency to be different.

15. The process system of claim 14, further comprising a tunable blocking capacitor connected between said substrate pedestal and ground for enabling selection of the self-bias of surfaces within said process chamber.

16. The process system of claim 14, further comprising an additional power source coupled to said plasma.

17. The process system of claim 16, wherein said additional power source is a microwave power source and said microwave power source is coupled to said plasma by an antennae.

18. The process system of claim 14, further comprising a third power supply for providing an RF bias to said substrate pedestal, the frequency of said RF bias being different to said first RF frequency and said second RF frequency.

19. The process system of claim 14, wherein said first RF frequency is in the range of 500 kHz to 2 MHz, and the second RF frequency is greater than or equal to 13.56 MHz.

20. The process system of claim 14, wherein said first RF frequency is greater than 2 MHz, and said second RF frequency is greater than or equal to 60 MHz.
